(19) United States
(12) Patent Application Publication
(10) Pub. No.: US 2014/0236508 A1
(43) Pub. Date: Aug. 21, 2014

(54) METHOD FOR ENERGY CONSUMPTION MONITORING AND CONTROL AND SYSTEM THEREFROM

(71) Applicant: Power One Data International, Inc., Mesa, AZ (US)

(72) Inventors: Michael McGOWAN, Phoenix, AZ (US); Sameer PATIL, Bangalore (IN); Mahesh H. KALAIAH, Bangalore (IN)

(73) Assignee: Power One Data International, Inc., Mesa, AZ (US)

(21) Appl. No.: 13/960,279

(22) Filed: Aug. 6, 2013

(30) Foreign Application Priority Data
Feb. 15, 2013 (IN) 692/CHE/2013

(51) Int. Cl. G01R 21/133

(52) U.S. Cl. CPC G01R 21/133
USPC 702/62

(57) ABSTRACT

The invention provides a method and system for managing energy consumption for efficient recording, monitoring, control of electricity or energy usage and payment collection for the same. The energy consumption recording method for managing energy consumption multiple host users, comprises steps for collating electricity meter data from each meter associated with the each host user, through a data concentrator unit, wherein the data concentrator unit comprises at least one sensor for each electricity source associated with the each meter. Method further includes a step for translating the electricity meter data from each meter into the meter indicative parameters for each host user, communicating these meter indicative parameters to a meter data management database, and recording the meter indicative parameters for each host user in the meter data management database. These recorded parameters include dynamic usage information and further used in analytics useful for monitoring, control and payment collections.

### CROSS-REFERENCE TO RELATED APPLICATIONS

This application claims priority to Indian Patent Application Serial No. 692/CHE/2013 filed Feb. 15, 2013, the content of which is incorporated herein by reference in its entirety.

### FIELD OF THE INVENTION

This invention pertains to utility meters and systems for metering energy, in general, and to methods and devices for recording and monitoring electrical energy consumption based at least on predetermined use limits.

### BACKGROUND OF THE INVENTION

An electricity meter or energy meter is a device that measures the amount of electric energy consumed by a residence, business, or an electrically powered device. Electricity meters operate by continuously measuring the instantaneous voltage (volts), current (amperes), and power factor and finding the product of these to give instantaneous electrical power (watts) which is then integrated against time to give energy used (in kilowatt-hours etc.), that is used as billing unit. Meters for smaller services (such as small residential customers) can be connected directly in-line between source and customer. For larger loads, for example, more than about 50 ampere of load, current transformers are used, so that the meter can be located other than in line with the service conductors. Periodic readings of electric meters establishes billing cycles and energy used during a cycle.

These electricity meters fall into three basic categories, electromechanical, electronic meters, and smart meters. Electromechanical meters are typically induction watt-hour meters and are the most common type of meters that are used. These meters operate by counting the revolutions of a non-magnetic, but electrically conductive, metal disc which is made to rotate at a speed proportional to the power passing through the meter. The number of revolutions is thus proportional to the energy usage. These meters are generally highly reliable, but cannot be used for remote or automated reading, and do not have data communicating abilities. The smart meters typically utilize electronic circuitry (in combination with the rotating disk) to permit at least limited two-way communication to/from the meter.

Such a smart meter records consumption of electric energy in intervals of an hour or less and communicates that information daily back to the utility for monitoring and billing purposes. Smart meters also enable two-way communication between the meter and the central system. Unlike home energy meters, smart meters can gather data for remote reporting. Such an advanced metering infrastructure (AMI) differs from traditional automatic meter reading (AMR) in that it enables two-way communications with the meter. Typically, the two-way communication is limited to reading the meter via a proprietary communications protocols that frequently is a limited range powerline carrier link.

It is common practice for utility companies to physically access meter information on only a monthly period. The electricity company typically bills the customer for the amount of energy used in the previous month or quarter. Thus, due to practical considerations, the billing cycles are fixed over a period of time, such as on a monthly basis. In some countries, if the utility provider believes that the customer may not pay the bill, a prepayment meter may be installed. Disadvantages of these included the need for installing a specialized device such as a special keyboard in addition to the meter and regular visits by dedicated personnel to access meter information for each user. The currently available re-charge mechanism require additional integration hardware and devices, and are not convenient. For example, often hardware such as magnetic reader or keypads are used which get affected by environment such as dust, water etc., and require their own maintenance and repair periodically. Further, when there are situations where customers use excess energy over the pre-assigned energy levels, existing systems are incapable of handling such infractions in a facile manner.

### OBJECTS OF THE INVENTION

Current methods for recording energy consumption do not include monitoring of the usage and any control features for the usage. Current systems are also not flexible in terms of pricing and payment options provided to the users. The system, methods and devices of the invention provide accurate monitoring of the usage and further provide control options to the energy/electricity provider for the usage and distribution of loads, as well as provide convenient solutions for the users and consumers of energy/electricity to pay for the usage. A unique advantage of the method, systems, and devices described herein is that these can be integrated into the existing systems and devices, thus reducing the burden of setting up a totally new infrastructure.

An object of the invention is to provide an energy consumption recording method for managing energy consumption for a plurality of host users, wherein each host user is provided with a meter for capturing electricity meter data. The method comprises collating electricity meter data from each meter associated with the each host user, through a data concentrator unit, translating the electricity meter data from each meter into the meter indicative parameters tor each host user; communicating the meter indicative parameters for each host user to a meter data management database; and recording the meter indicative parameters for each host user in the meter data management database. These recorded meter indicative parameters contain dynamic and current information about usage of the energy/electricity, and these parameters are used for different control, monitoring, and payment/revenue objectives by the provider/manager of the energy/electricity.

Another object of the invention is to provide an energy consumption recording system that uses the above described method.

Yet another object of the invention is to provide a system for managing energy consumption using the monitoring and control features described herein.

### BRIEF SUMMARY OF THE INVENTION

In one aspect, an energy consumption recording method for managing energy consumption for a plurality of host users is provided. Each host user is provided with a meter for capturing electricity meter data. The method comprises steps for collating electricity meter data from each meter associated with the each host user, through a data concentrator unit, wherein the data concentrator unit comprises at least one sensor for each electricity source associated with the each meter. Method further includes as step for translating the electricity meter data from each meter into the meter indicative parameters for each host user, communicating these meter indicative parameters to a meter data management database, and recording the meter indicative parameters for each host user in the meter data management database.

In another aspect, a system for managing energy consumption is provided for efficient monitoring, control and payment collection. The system comprises a plurality of meters for capturing electricity meter data for respective plurality of host users, a data concentrator unit for collating the electricity meter data from each of the plurality of meters associated with the each host user. The data concentrator unit includes a sensor for each electricity source associated with the each meter. The system further includes a meter data acquisition module for receiving the electricity meter data from the data concentrator unit and translating the electricity meter data into the meter indicative parameters for each host user. A meter data management database is used for receiving and recording the meter indicative data from the meter data acquisition module. For monitoring, and control, an analysis and reporting module is used for using the meter indicative data to generate one or more consumption analytics or one or more reports. These analytics and reports are used by a controller module for issuing necessary commands to at least one of each meter, a host user device, a display device, or a high powered device.

### BRIEF DESCRIPTION OF THE SEVERAL VIEWS OF THE DRAWINGS

These and other features, aspects, and advantages of the present invention will become better understood when the following detailed description is read with reference to the accompanying drawings in which like reference numerals represent corresponding parts throughout the drawings, wherein:

FIG. 1 is a diagrammatic representation of a system for managing energy consumption for a multiple host users;

FIG. 2 is a diagrammatic representation of a system of FIG. 1 using. GPRS as a communication interface; and

FIG. 3 is a flowchart representation of an energy consumption recording method that is used by systems of FIG. 1 and FIG. 2.

### DETAILED DESCRIPTION OF THE INVENTION

As used herein and in the claims, the singular forms “a,” “an” and “the” include the plural reference unless the context clearly indicates otherwise.

The invention provides an energy consumption recording method and system for managing energy consumption for a plurality of host users, wherein each host user is provided with a meter for capturing electricity meter data.

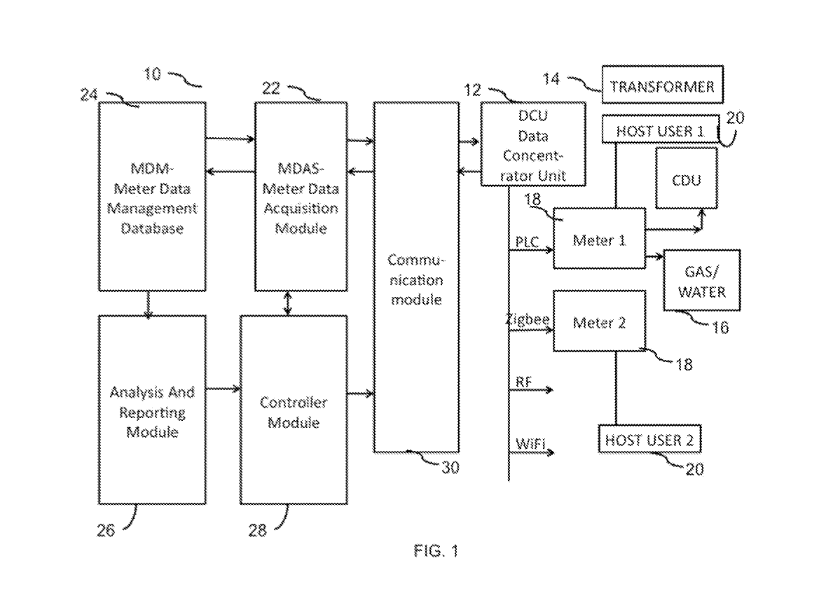

The system 10 for managing energy consumption data is shown in FIG. 1, and includes a data concentrator unit 12 that is typically coupled to a transformer 14 that receives electricity from a feeder (not shown). The data concentrator unit is coupled to multiple meters shown as reference numerals 18. The meters as referred herein are smart meters in one example, that are capable of two way communication as is explained in more detail hereinafter. The meters include microcontrollers and registers for enabling the two-way communication. In another exemplary implementation, the meter is a standard meter with additional features of being controlled from a central server. The meter includes latch relays to respond to triggers and signals from a controller module as described herein below.

These meters 18 in turn are connected to respective host users 20 to record the electricity usage data for the respective hosts. In a specific embodiment, the data concentrator unit comprises at least one sensor (not shown in FIG. 1) for each electricity source associated with the each meter. For example, the electricity source may be a utility source which uses thermal energy, or it may be an alternate electricity source such as a generator source (including diesel generators, steam generators and the like), solar source, a wind energy source, or the like. Thus the sensor has the ability to detect and report to the data concentrator unit which type of electricity source is connected to the host user. It would be appreciated by those skilled in the art that a group of host users may be tagged together to form an area user group, and the same techniques as described herein below will be applicable to such area groups. In one specific embodiment, along with the electricity meters (referred generally as “meters”), one or more other utility meter shown by reference numeral 16 may also be coupled to the data concentrator unit, and it's inputs may also be similarly captured by the data concentrator unit to provided integrated energy meter data that are translated into meter indicative parameters. The utility meter may be a water meter, and a gas meter or such combinations as well. The communication between the utility meters and data concentrator unit may be through the meters themselves on a dedicated communication platform or through other communication means such as radio frequency means, infra red means, zigbee, wifi, Bluetooth and the like, and combinations thereof.

The system 10 further includes a meter data acquisition module 22 for receiving the electricity meter data from the data concentrator unit 12 and translating the electricity meter data into the meter indicative parameters for each host user. It would be understood by those skilled in the art that the translating is through a standard communication protocol or a specially adapted communication protocol. These meter indicative parameters are sent to a meter data management database 24. The meter indicative parameters as described herein include consumption of electricity from the each electricity source. Further in the exemplary embodiment, the meter indicative parameters are based on (or translated as at least one of electricity consumption data, tariff data, or combination thereof. The tariff data is typically based on a flat rate, slab rate, or time of use. In an exemplary embodiment, the meter indicative parameters for each host user are recorded at discrete instances of time. It is not uncommon for electric utilities to utilize both simple and complex tariffs. The tariffs may be time of use type tariffs, or may be changed from time to time or on predetermined dates to provide for various time of use type of rates.

The system 10 further includes an analysis and reporting module 26 for using the meter indicative data to generate one or more consumption analytics or one or more reports. The analytics is used for further monitoring and control of the usage or distribution for efficient management of electricity. One exemplary analytics is generating instantaneous consumption data. The instantaneous consumption may be collected at discrete time intervals, for example 15 minutes in one example. In another example, the analytics includes generating an average consumption data for a group of host users. In another example, the analytics includes a cumulative usage data for at least one host user, based on the recording at the discrete instances of time. In a further analytics, a comparison of the cumulative usage data for the at least one host user may be done with a predetermined use limit. Based on this analysis, a usage difference between the predetermined use limit and the cumulative usage data for the at least one host user is determined. In an exemplary embodiment, the analytics may also include translating the predetermined use limit and cumulative usage data into a payment related data for the host user. The payment related data may be pre-paid data, excess use data and the like that may be used for further analytics, or for generating alerts and intimations for the host user. The payment related data in one example is communicated as post-paid payment option. It would be appreciated by those skilled in the art, that the same meter can be used now for both pre-paid or post-paid payment options. Thus the system 10 also allows for variable pricing structures based as the meter and usage monitoring is accurate and provides an ability to price based on usage criterion, or time criterion or combinations thereof, and in other manner derived from analytics done of meter indicative data.

It would also be appreciated by those skilled in the art that the analysis and reporting module may send the different analytics reports to a display device or a host or a central computer or such communication device that can be accessed by a user, manager, administrator for viewing and for further planning and decision making.

The system 10 also includes a controller module 28 for issuing commands to at least one of a meter, a host user device, a display device, or a high powered device. In one exemplary embodiment, the controller module 28 generates a pulse trigger when at least one of the instantaneous consumption data generated by the analytics and control module, exceeds a pre-set demand limit, or when the average consumption data exceeds a maximum demand limit. The pulse trigger as referred herein may include at least one of a short messaging service message, or an electronic, mail message to alert the host user. Alternately, the controller module may trigger a disconnect signal for high powered devices of the host user, or a disconnect signal to at least one meter. In another example, the controller module generates a usage trigger for the at least one host user if the usage difference is within a prescribed tolerance range or an intimation range. The usage trigger can be a message through any one of a short messaging servicing, or an email service, the usage trigger may be implemented as a sound alarm, a visual alarm, or combinations thereof or the host user device. In a further exemplary embodiment, the controller module sends a disconnect supply signal to the at least one host user if is the usage difference exceeds the intimation range. It would be appreciated by those skilled in the art that the controller module may be fully or partly integrated with the analytics module or may be partly integrated with a host or central communication device or may be fully or partly integrated with the MIDAS. In one particular embodiment, the controller module 28 is fully integrated with the MDAS 24.

The system 10 further comprises a communicating module 30 for communicating via, a communication protocol between the meter data acquisition module, the meter data management database, the analysis module, the controller module, the data concentrator unit, the meters (electricity and utility), the a host user or communication device, a display device (CDU customer display unit), or a high powered device. It would be understood by those skilled, in the art that the communicating between the meters, utility meters, data concentrator unit, CDU can be directly through the meters/utility meters, or through an external communicating device through a wired means, wireless means, radio frequency means, wifi, Zigbee, PLCs (Progammable Logic Controllers), PSTN (Public Switched Telephone Network) or other such communication means or combinations thereof. The system 10 further comprises a cloud storage module for storing the meter data management database and the data from the data concentrator unit.

Thus the system 10 provides real time analysis, monitoring and control of the energy consumption of multiple users. Aspects of system 10 are implemented in one example via API's (application protocol interfaces). Aspects of the system 10 may also be web enabled allowing access via Internet.

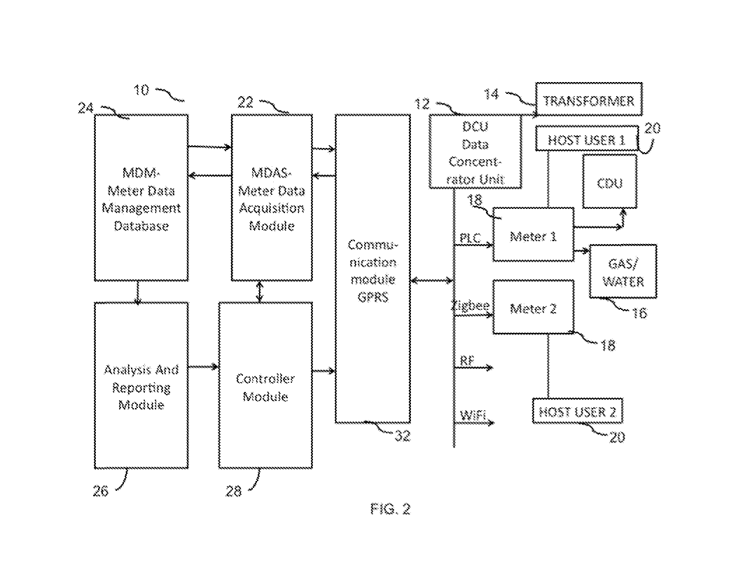

In one exemplary embodiment as shown in FIG. 2, the communication module 32 may include GPRS (General Packet Radio Service) in the system 10 to enable communication with the meters, and include different features to communicate to host user devices that are enabled through GPRS.

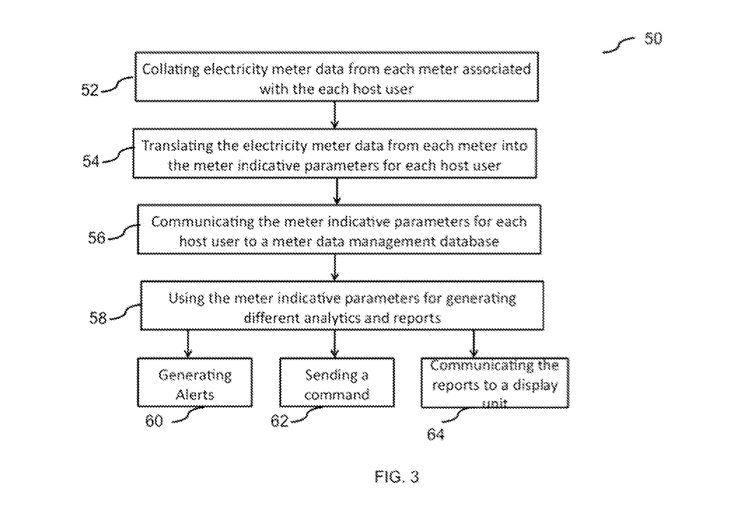

The invention also provides an energy consumption recording method that is used by the system 10 as explained herein above. The illustrative method steps are shown in a flowchart 50 of FIG. 3. The method includes a step 52 for collating electricity meter data from each meter associated with the each host user, through the data concentrator unit as explained herein above. In one specific embodiment, the method further includes accepting inputs from one other utility meter as explained herein above, where the at least one utility meter includes a water meter, or a gas meter. The method further includes a step 54 for translating the electricity meter data from each meter into the meter indicative parameters for each host user. In one specific implementation the meter indicative parameters are recorded at discrete instances of time.

At step 56, the method includes communicating the meter indicative parameters for each host user to a meter data management database. At step 58 the method further includes using these meter indicative parameters for different analytics and reports. For example, the method in one implementation generates instantaneous consumption data, that is further used to generate an average consumption data for a host user or for a group of host users. In a further implementation the analytics includes generating a cumulative usage data for at least one host user based on the recording at the discrete instances of time. In a further analytics, a comparison of the cumulative usage data for the at least one host user may be done with a predetermined use limit. Based on this analysis, a usage difference between the predetermined use limit and the cumulative usage data for the at least one host user is determined. The corresponding reports may be based on the instantaneous usage data, the cumulative usage data, exceeding tolerance data, number and date of intimations data, and combination thereof. In one specific example, the meter indicative parameters are tracked for hourly and daily electricity usage, and such information is further used to drive measures to control energy costs and improve efficiency.

In a further implementation, the method includes a step 60 for generating different alerts based on the analytics. For example the method includes generating a pulse trigger when at least one of the instantaneous consumption data exceeds a pre-set demand limit, or when the average consumption data exceeds a maximum demand limit. The pulse trigger as referred herein may include at least one of a short messaging service message, an electronic mail message, a disconnect signal for high powered devices, a disconnect signal to at least one meter or combinations thereof. A usage trigger is generated in another implementation, for the at least one host user if the usage difference is within a prescribed tolerance range or an intimation range. The usage trigger is at least one of a short messaging servicing, an email service, a sound alarm, a visual alarm, or combinations thereof

Further the method includes a step 62 for sending a command to system 10 based on the analytics. For example the command may include a disconnect supply signal to the at least one host user if the usage difference exceeds the intimation range. Alternately, the method includes a step 64 for communicating the reports to a display unit of a communication device of the host user or the utility provider or a manager of the host user energy service. The communication module may be integrated into the MDAS. Further, using a GPRS system, MDAS may be enabled to directly communicate with the individual meters.

It would be appreciated by those skilled in the art that the aspects of the invention as described herein provide several advantages over existing meters and metering services. On such advantage is implementation of pre-paid or post paid metering service through which a host user is now enabled to purchase a pre-determined amount of metered energy. Once the purchased amount of metered energy is about to be exhausted the system and method described herein will send appropriate triggers to the user to facilitate purchasing or recharging the host user account with the desired amount of metered energy. Similarly, based on the usage, the host user may be easily connected or disconnected by remote commands. Further, the invention enables on demand data collection, that may be instantaneous data or end of day data or cumulative for any pre-determined period. The invention also allows for demand side management of electricity. Thus very efficiently based on profile of usage of live data, the system may turn off supply to some host users or host devices during peak hours of demand that may be based on maximum consumption, which in turn may be determined by the utility provider or the owner or manager of the host users energy services. Similarly, the host users may be reconnected, waned of, or certain loads may be actively turned off based on demand and supply metrics. Further the invention enables integrated metering by allowing the inputs of other utility meters to be routed through the system.

A distinct advantage of the method and the system of the invention is the relatively less chances of error in monitoring the usage, billing and collections due to higher accuracy built therein. Specifically, the method and systems described herein improve reading accuracy, and data quality that eliminates the use or need of any estimated readings. Further the consumer meters can be read dynamically at a central remote facility, enabling better control and monitoring. Further, the embodiments described herein allow tamper proof systems over the existing smart card readers.

Another distinct advantage of the system and method described herein is providing flexible billing options using the analytics on meter indicative data. A flexibility may be provided to the user on choice of billing date, month-to-date bills may be generated, projected month-end bills may be generated using past consumption/usage patterns.

Yet another advantage of the system and method described herein is that the same meter may be used as prepaid or postpaid without changing the hardware associated with it, thus ensuring ease of migration from one operating mode to the other, such as prepaid to postpaid.

A further advantage stems from the communication abilities of the system and method described herein that enable the meter network to be rendered as a smart meter network. This simplifies the existing infrastructure and allows for linking a variety of other infrastructures to this system. For example, recharging or payment of bills may be through a mobile phone infrastructure. The meter data collection and transmission is highly secure due to the method employed herein. Further, cloud implementation of the method allows for reduced infrastructure costs, and limits the costs to only operating costs.

Further the method and systems described herein enhances power quality and reliability through better voltage and system load monitoring, due to efficient monitoring of electricity usage as described herein. Grid problems, power quality issues may be effectively captured and addressed and grid planning can be effectively improved. Similarly it will be possible to detect and track energy thefts through efficient monitoring as provided by the system and method as described herein. The power outage management system is greatly enhanced (through links with GIS and real time consumer status) resulting in overall improved system planning process and improved distribution asset management. Further, the meter indicative parameters, in a specific implementation allow for monitoring and assessing the associated equipment health and condition-based monitoring, and measures are taken using the data from the meter indicative parameters or analytics on the data to maximize asset utilization and life, thus optimizing maintenance, capital and spending on operations and maintenance.

Advanced distribution management system (distribution automation, integrated operation of Demand Response) is easily integrated with the system described herein. This in turn leads to better management of power supply and demand, and distribution network management.

Other such advantages will become apparent to those skilled in the art.

While only certain features of the invention have been illustrated and described herein, many modifications and changes will occur to those skilled in the art. It is, therefore, to be understood that the appended claims are intended to cover all such modifications and charges as fall within the true spirit of the invention.

We claim:

1. An energy consumption recording method for managing energy consumption for a plurality of host users, wherein each host user is provided with a meter for capturing electricity meter data, the method comprising:
collating electricity meter data from each meter associated with the each host user, through a data concentrator unit, wherein the data concentrator unit comprises at least one sensor for each electricity source associated with the each meter;
translating the electricity meter data from each meter into the meter indicative parameters for each host user;
communicating the meter indicative parameters for each host user to a meter data management database; and
recording the meter indicative parameters for each host user in the meter data management database.

2. The energy consumption recording method of claim 1 wherein the translating is through a standard communication protocol or a specially adapted communication protocol.

3. The energy consumption recording method of claim 1 wherein communicating is via a wired means, wireless means, radio frequency means.

4. The energy consumption recording method of claim 1 wherein the meter indicative parameters include data representative of consumption of electricity from the each electricity source.

5. The energy consumption recording method of claim 1 wherein the meter indicative parameters are based on at least one of electricity consumption data, tariff data, or combination thereof.

6. The energy consumption recording method of claim 5 wherein the tariff data is based on a flat rate, slab rate, or time of use.

7. The energy consumption recording method of claim 1 further comprising accepting inputs from one other utility meter, wherein the at least one utility meter comprises a water meter, and a gas meter.

8. The energy consumption recording method of claim 1 further comprising: recording the meter indicative parameters for each host user at discrete instances of time; and generating instantaneous consumption data.

9. The energy consumption recording method of claim 8 further comprising generating an average consumption data for at least one host user or a group of host users.

10. The energy consumption recording method of claim 9 further comprising generating a pulse trigger when at least one of the instantaneous consumption data exceeds a pre-set demand limit, or when the average consumption data exceeds a maximum demand limit.

11. The energy consumption recording method of claim 10 wherein the pulse trigger comprises at least one of a short messaging service message, an electronic mail message, a disconnect signal for high powered devices, a disconnect signal to at least one meter or combinations thereof.

12. The energy consumption recording method of claim 8 further comprising generating a cumulative usage data for at least one host user based on the recording at the discrete instances of time.

13. The energy consumption recording method of claim 12 further comprising comparing the cumulative usage data for the at least one host user with a predetermined use limit.

14. The energy consumption recording method of claim 13 further comprising determining a usage difference between the predetermined use limit and the cumulative usage data for the at least one host user.

15. The energy consumption recording method of claim 14 further comprising translating the predetermined use limit and cumulative usage data into a payment related data for the host user.

16. The energy consumption recording method of claim 14 further comprising generating a usage trigger for the at least one host user if the usage difference is within a prescribed tolerance range or an intimation range.

17. The energy consumption recording method of claim 16 wherein the usage trigger is at least one of a short messaging servicing, an email service, a sound alarm, a visual alarm, or combinations thereof

18. The energy consumption recording method of claim 17 further comprising sending a disconnect supply signal to the at least one host user if is the usage difference exceeds the intimation range.

19. The energy consumption recording method of claim 14 further comprising generating one or more reports on the instantaneous usage data, the cumulative usage data, exceeding tolerance data, number and date of intimations data, and combination thereof.

20. The energy consumption recording method of claim 19 further comprising communicating the one or more reports to a display unit.

21. The energy consumption recording method of claim 1 wherein the meter data management database and the data concentrator unit is stored on a cloud system.

22. An energy consumption recording system that uses the method of claim 1.

23. A system for managing energy consumption, the system comprising:
a plurality of meters for capturing electricity meter data for respective plurality of host users;
a data concentrator unit for collating the electricity meter data from each of the plurality of meters associated with the each host user, wherein the data concentrator unit comprises at least one sensor for each electricity source associated with the each meter of the plurality of meters;
a meter data acquisition module for receiving the electricity meter data from the data concentrator unit and translating the electricity meter data into the meter indicative parameters for each host user;
a meter data management database for receiving the meter indicative data from the meter data acquisition module;
an analysis and reporting module for using the meter indicative data to generate one or more consumption analytics or one or more reports; and
a controller module for issuing commands to at least one of the each meter, a host user device, a display device, or a high powered device.

24. The system for monitoring energy consumption data of claim 23 further comprising a communicating module for communicating between the meter data acquisition module, the meter data management database, the analysis module, the controller module, the plurality of meters, the host user device, the display device, or the high powered device.

25. The system for monitoring energy consumption data of claim 23 further comprising a cloud storage module for storing the meter data management database and the data concentrator unit.

26. The system for monitoring energy consumption data of claim 24 wherein the each meter is configured for at least one of pre-payment option or a post-payment option.
